(19) United States
(12) Patent Application Publication
(10) Pub. No.: US 2012/0161111 A1
(43) Pub. Date: Jun. 28, 2012

(54) WHITE ORGANIC LIGHT ELECTROLUMINESCENCE DEVICE

(75) Inventors: Po-Hsuan Chiang, New Taipei City (TW); Chun-Liang Lin, New Taipei City (TW); Chieh-Wei Chen, Taichung City (TW)

(73) Assignee: AU OPTRONICS CORPORATION, Hsinchu (TW)

(21) Appl. No.: 13/069,377

(22) Filed: Mar. 22, 2011

(30) Foreign Application Priority Data
Dec. 23, 2010 (TW) 99145589

(51) Int. Cl. H01L 51/52

(52) U.S. Cl. 257/40; 257/E51.022

(57) ABSTRACT

A white organic light electroluminescence device includes a first light emitting unit, a second light emitting unit and a connecting layer between the first light emitting unit and the second light emitting unit. The connecting layer electrically connects the first light emitting unit and the second light emitting unit in series. The first light emitting unit includes a first electrode layer, a first light emitting layer on first electrode layer, and an intrinsic layer. The first light emitting layer has a first blue light emitting layer and a red light emitting layer, and the intrinsic layer is between the first blue light emitting layer and the red light emitting layer. The second light emitting unit includes a second light emitting layer and a second electrode layer on the second light emitting layer. The second light emitting layer has a second blue light emitting layer and a green light emitting layer.

### CROSS-REFERENCE TO RELATED APPLICATION

This application claims the priority benefit of Taiwan application serial no. 99145589, filed Dec. 23, 2010. The entirety of the above-mentioned patent application is hereby incorporated by reference herein and made a part of this specification.

### BACKGROUND OF THE INVENTION

1. Field of the Invention

The invention relates to an organic light emitting device and more particularly to a white organic light electroluminescence device.

2. Description of Related Art

Along with the progress in semiconductor technology, organic light emitting diodes (OLEDs) now have high brightness output. Moreover, being energy saving, low voltage driven, and mercury free, OLEDs are widely applied in displays and illumination. A common white OLED device is generally obtained by mixing a red light emitting material, a green light emitting material, and a blue light emitting material. However, the efficiency and the lifespan of the device are restrained when these three lights are prepared in a single device.

In order to elongate the lifespan of the white OLED device, a stacked white OLED device is now disclosed, where a blue OLED device and a red-green OLED device are stacked for the emitted lights to be mixed into a white light. However, as the light emitting efficiencies and lifespan of the red-green light emitting material and the blue light emitting material are not the same, the light emitting efficiency of the stacked white OLED device remains restrained and the light color adjustment of the white light is difficult. In addition, in the red-green light emitting material of the red-green OLED device, the red light emitting material and the green light emitting material are co-evaporated to form a layer of light emitting layer. Here, a concentration of the red light emitting material in the light emitting layer has to be maintained under 1%. Nevertheless, the rate of a general evaporating process is 1 A/s and the evaporating rate of the red light emitting material thus has to be maintained under 0.01 A/s. In other words, the evaporating process of the red-green light emitting material is hard to control and consequently leads to difficult slight-adjustment in the light color of the red-green OLED device.

### SUMMARY OF THE INVENTION

The invention is directed to a white organic light electroluminescence device capable of improving the poor light emitting efficiency and difficult light color adjustment of the traditional stacked white OLED device.

The invention is directed to a white organic light electroluminescence device including a first light emitting unit, a second light emitting unit, and a connecting layer disposed between the first light emitting unit and the second light emitting unit. The connecting layer electrically connects the first light emitting unit and the second light emitting unit in series. The first light emitting unit includes a first electrode layer, a first light emitting layer, and an intrinsic layer. The first light emitting layer is disposed on the first electrode layer, and includes a first blue light emitting layer and a red light emitting layer. The intrinsic layer is disposed between the first blue light emitting layer and the red light emitting layer. The second light emitting unit includes a second light emitting layer and a second electrode layer. The second light emitting layer includes a second blue light emitting layer and a green light emitting layer. The second electrode layer is disposed on the second light emitting layer.

In light of the foregoing, in the white organic light electroluminescence device of the invention, the blue, red, and green light emitting layers are separate layers, such that the light color of the white light can be adjusted by controlling the blue, red, and green light emitting layers. Further, the first light emitting layer of the first light emitting unit in the invention includes the first blue light emitting layer and the red light emitting layer, where an intrinsic layer is further disposed between the first blue light emitting layer and the red light emitting layer. The intrinsic layer transfers the triplet excitons not utilized in the blue light emitting layer to the red light emitting layer for the triplet excitons to be used by the red light emitting layer to emit red light. Therefore, the red, green, and blue light emitting layers are designed as individual layers in the invention and can be used to generate white light.

In order to make the aforementioned and other features and advantages of the invention more comprehensible, several embodiments accompanied with figures are described in detail below.

### BRIEF DESCRIPTION OF THE DRAWINGS

The accompanying drawings are included to provide further understanding, and are incorporated in and constitute a part of this specification. The drawings illustrate embodiments and, together with the description, serve to explain the principles of the invention.

FIG. 1 is a schematic cross-sectional view illustrating a white organic light electroluminescence device according to an embodiment of the invention.

FIG. 2 is a diagram illustrating a relationship of a light emitting wavelength versus a light emitting intensity of a first light emitting layer and a second light emitting layer of the white organic light electroluminescence device in FIG. 1.

FIG. 3 is a schematic diagram showing an energy transfer of the first light emitting layer of the white organic light electroluminescence device in FIG. 1.

### DESCRIPTION OF EMBODIMENTS

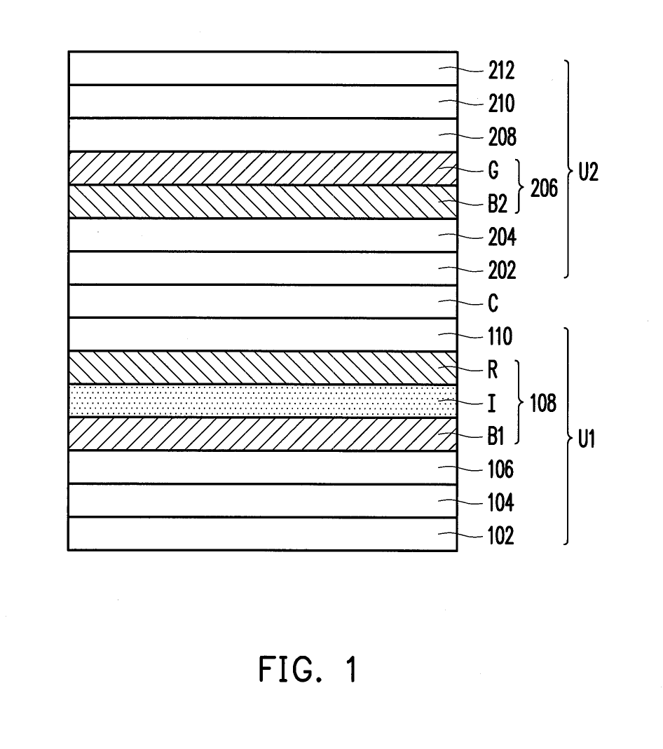

FIG. 1 is a schematic cross-sectional view illustrating a white organic light electroluminescence device according to an embodiment of the invention. Referring to FIG. 1, a white organic light electroluminescence device of the present embodiment includes a first light emitting unit U1, a second light emitting unit U2, and a connecting layer C disposed between the first light emitting unit U1 and the second light emitting unit U2.

The first light emitting unit U1 includes a first electrode layer 102 and a first light emitting layer 108. According to the present embodiment, the first electrode layer 102 is a transparent conductive layer made of a metal oxide, for example, indium-tin oxide (ITO), indium-zinc oxide (IZO), gallium-zinc oxide (GZO), zinc-tin oxide (ZTO), or other metal oxides.

The first light emitting layer 108 is disposed on the first electrode layer 102. The first light emitting layer 108 includes a first blue light emitting layer B1, a red light emitting layer R, and an intrinsic layer I sandwiched between the first blue light emitting layer B1 and the red light emitting layer R. The first blue light emitting layer B1 is fabricated with a blue fluorescent material or a blue phosphorescence material. The red light emitting layer R is fabricated with a red fluorescent material or a red phosphorescence material.

Generally, the light emitting efficiency and the lifespan of the red phosphorescence material is more favorable than those of the red fluorescent material. Thus, the red light emitting layer R of the first light emitting layer 108 in the present embodiment is preferably fabricated with a red phosphorescence material. The light emitting wavelength of the red phosphorescence material ranges from 590 nanometer (nm) to 650 nm.

In addition, the light emitting efficiency of the blue phosphorescence material is more favorable than that of the blue fluorescent material; however, the lifespan of the blue phosphorescence material is shorter than that of the blue fluorescent material. Thus, the first blue light emitting layer B1 of the first light emitting layer 108 in the present embodiment is fabricated with a blue fluorescent material. The light emitting wavelength of the blue fluorescent material ranges from, for example, 440 nm to 470 nm.

Particularly, the intrinsic layer I is disposed between the first blue light emitting layer B1 and the red light emitting layer R in the present embodiment. According to the present embodiment, a thickness of the intrinsic layer ranges from 1 nm to 40 nm and preferably ranges from 1 nm to 10 nm. A triplet energy level T₁ of the intrinsic layer I ranges from a triplet energy level T₁ of the first blue light emitting layer B1 to a triplet energy level T₁ of the red light emitting layer R as shown in FIG. 3. In details, in the present embodiment, the triplet energy level T₁ of the intrinsic layer I ranges from a triplet energy level T₁ of a blue fluorescent material B1 to a triplet energy level T₁ of a red phosphorescence material R. According to an embodiment, when N,N′-di-1 -naphthalenyl-N,N′-diphenyl-[1,1′:4′,1″:4″,1″′-quaterphenyl]-4,4″′-diamine (4P-NPD) is adopted for the blue fluorescent material B1 and iridium(III)bis(2-methyldibenzo-[f,h]quinoxaline)(acetyl-acetonate) (Ir(MDQ)2(acac)) or {bis-2-(2′-benzo[4,5-a] thienyl)pyridinato-N,C3′}iridium (acetylacetonate) ((Btp)2Ir(acac)) is adopted for the red phosphorescence material R, then 4P-NPD can also be used for the intrinsic layer I.

Conventionally, the blue light of the blue fluorescent material B1 is formed by the blue light phosphorescence E1 generated by exciting singlet excitons. Moreover, most of the triplet excitons of the blue fluorescent material B1 can not be utilized. Thus, through the disposition of the intrinsic layer I in the present embodiment, the triplet excitons of the blue fluorescent material B1 can be transferred to the red phosphorescence material through a transfer T of the intrinsic layer I. Consequently, the triplet excitons can be used by the red phosphorescence material to emit a red phosphorescence E2. In other words, in the present embodiment, the triplet excitons of the blue fluorescent material B1 that can not be used originally can be transferred to the red phosphorescence material through the intrinsic layer I to generate the red phosphorescence E2. Therefore, the first light emitting unit U1 of the present embodiment can emit a blue light and a red light.

The second light emitting unit U2 includes a second light emitting layer 206 and a second electrode layer 212. The second light emitting layer 206 includes a second blue light emitting layer B2 and a green light emitting layer G. The second blue light emitting layer B2 is fabricated with a blue fluorescent material or a blue phosphorescence material. The green light emitting layer G is fabricated with a green fluorescent material or a green phosphorescence material.

In general, the light emitting efficiency and the lifespan of the green phosphorescence material is more favorable than those of the green fluorescent material. Thus, the green light emitting layer G of the second light emitting layer 206 in the present embodiment is preferably fabricated with a green phosphorescence material. The green phosphorescence material has a light emitting wavelength ranging from 500 nm to 570 nm, and is fabricated with fac-tris(2-phenylpyridine iridium (Ir(ppy)3) or [tris-fac-(2-cyclohexenylpyridine) iridium (III) (Ir(chpy)3).

In addition, as illustrated above, the light emitting efficiency of the blue phosphorescence material is more favorable than that of the blue fluorescent material; however, the lifespan of the blue phosphorescence material is shorter than that of the blue fluorescent material. As the first blue light emitting layer B1 of the first light emitting layer 108 of the first light emitting unit U1 is fabricated with the blue fluorescent material, the second blue light emitting layer B2 of the second light emitting layer 206 of the second light emitting unit U2 is fabricated with the blue phosphorescence material in the present embodiment. The blue phosphorescence material has a light emitting wavelength ranging from 470 nm to 480 nm, and is fabricated with iridium (III) bis(4′6′-difluorophrnylpyridinato) tetrakis(1-pyrazolyl)borate (Fir6) or iridium(III)bis(4,6-(di-fluorophenyl)-pyridinato-N,C2′)picolinate (FIrpic).

Accordingly, the first blue light emitting layer B1 of the first light emitting layer 108 of the first light emitting unit U1 is fabricated with the blue fluorescent material, the second blue light emitting layer B2 of the second light emitting layer 206 of the second light emitting unit U2 is fabricated with the blue phosphorescence material in the present embodiment. As a consequence, the blue fluorescent material having long lifespan and deeper light color and the blue phosphorescence material having high light emitting efficiency are conducted into the white organic light electroluminescence device simultaneously in the present embodiment to complement each other.

Furthermore, the second electrode layer 212 is disposed on the second light emitting layer 206. According to the present embodiment, the second electrode layer 212 includes a metal electrode material, for example, alloy, alloy/lithium alloy, magnesium silver alloy, or other metal material.

Additionally, the connecting layer C is disposed between the first light emitting unit U1 and the second light emitting unit U2 and electrically connects the first light emitting unit U1 and the second light emitting unit U2 in series. According to the present embodiment, the connecting layer C includes a conductive material, for example, molybdenum trioxide (MoO₃) or tungsten trioxide (WO₃).

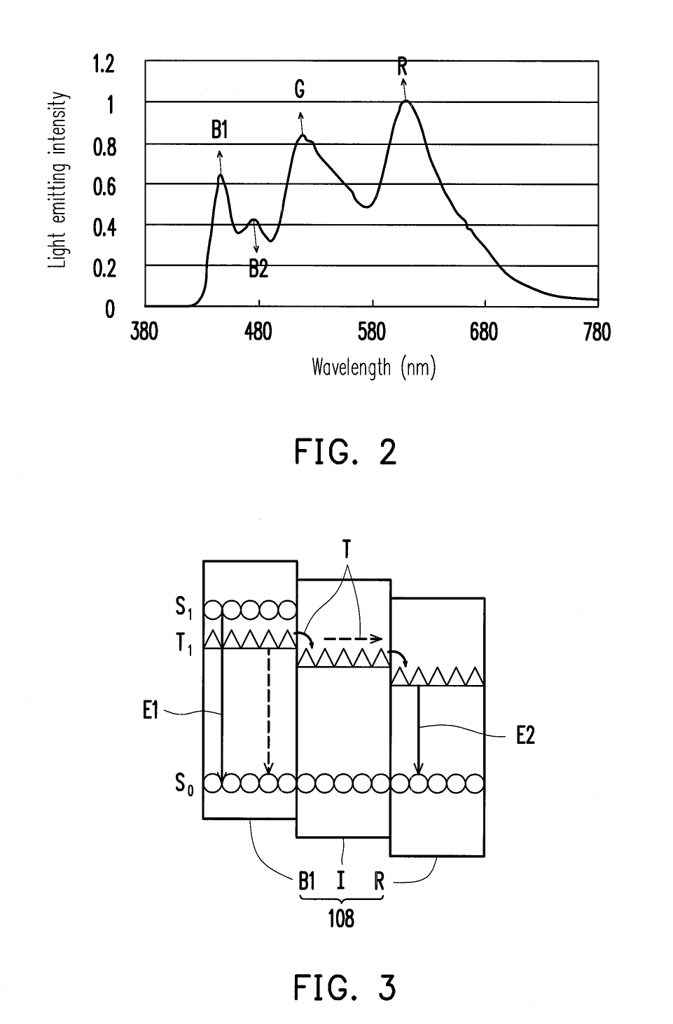

According to the design of the first light emitting unit U1 and the second light emitting unit U2, the wavelength distribution of the color light emitted by the first light emitting layer 108 and the second light emitting layer 206 is depicted in FIG. 2. The first blue light emitting layer B1 of the first light emitting layer 108 is capable of emitting a blue color light with a wavelength ranging from 440 nm to 470 nm. The red light emitting layer R of the first light emitting layer 108 is capable of emitting a red color light with a wavelength ranging from 590 nm to 650 nm. The second blue light emitting layer B2 of the second light emitting layer 206 is capable of emitting a blue color light with a wavelength ranging from 470 nm to 480 nm. The green light emitting layer G of the second light emitting layer 206 is capable of emitting a green color light with a wavelength ranging from 500 nm to 570 nm. Thus, the color lights emitted by the first blue light emitting layer B1 of the first light emitting layer 108 and the red light emitting layer R and the second blue light emitting layer B2 of the second light emitting layer 206 and the green light emitting layer G can be mixed into a white light for the light emitting device of the present embodiment to emit a white light.

Moreover, in the present embodiment, in order to enhance an electron-hole combination rate of the first light emitting layer 108 in the first light emitting unit U1 to increase the light emitting efficiency of the first light emitting unit U1, a first hole injection layer 104 is disposed between the first electrode layer 102 and the first light emitting layer 105, a first hole transport layer 106 is disposed between the first electrode layer 102 and the first light emitting layer 105, and a first electron transport layer 110 is disposed between the connecting layer C and the first light emitting layer 108. Similarly, in order to enhance an electron-hole combination rate of the second light emitting layer 206 in the second light emitting unit U2 to increase the light emitting efficiency of the second light emitting unit U2, a second hole injection layer 202 is further disposed between the second light emitting layer 206 and the connecting layer C, a second hole transport layer 204 is disposed between the second light emitting layer 206 and the connecting layer C, a second electron injection layer 210 is disposed between the second light emitting layer 206 and the second electrode layer 212, and a second electron transport layer 208 is disposed between the second light emitting layer 206 and the second electrode layer 212.

It should be noted that the disposition of the electron injection layer, the electron transport layer, the hole injection layer, and the hole transport layer in the first light emitting unit U1 and the second light emitting unit U2 is not limited in the invention. It should be noted that the number of layers of the electron injection layer, the electron transport layer, the hole injection layer, and the hole transport layer disposed in the first light emitting unit U1 and the second light emitting unit U2 is not limited in the invention. In other words, the electron injection layer, the electron transport layer, the hole injection layer, and the hole transport layer to be disposed are determined by the materials selected for fabricating the first electrode layer 102, the first light emitting layer 108, the second light emitting layer 206, the second electrode layer 212, and the connecting layer C in the first light emitting unit U1 and the second light emitting unit U2.

In addition, in the embodiment of FIG. 1, the second light emitting unit U2 is disposed on the first light emitting unit U1 for illustration. However, the invention is not limited thereto. According to other embodiments, the first light emitting unit U1 can also be disposed on the second light emitting unit U2. Or, the first light emitting layer 108 can be disposed in the second light emitting unit U2 and the second light emitting layer 206 is disposed in the first light emitting unit U1 (that is, the positions of the first light emitting layer 108 and the second light emitting layer 206 are interchanged). The materials of the light emitting units shown above are organic, for examples.

Moreover, although the white organic light electroluminescence device of the present embodiment adopts two light emitting units as an example, the invention does not limit the number of light emitting units stacked in the white organic light electroluminescence device. In other words, three or more than three light emitting units can be stacked in the white organic light electroluminescence device in other embodiments.

In summary, in the white organic light electroluminescence device of the invention, the blue, red, and green light emitting layers are separate layers, such that the light color (color temperature) of the white light can be adjusted by controlling light emitting spectrums of the blue, red, and green light emitting layers.

Further, the red light emitting layer and the green light emitting layer of the present embodiment do not to be co-evaporated. The red light emitting layer transfers the triplet excitons that can not be used in the blue light emitting layer to the red light emitting layer through the intrinsic layer, such that the triplet excitons can be utilized by the red light emitting layer to emit a red light. Therefore, the red, green, and blue light emitting layers are designed as individual layers in the invention and can be used to generate a white light by mixing the color lights emitted by the light emitting layers.

It will be apparent to those skilled in the art that various modifications and variations can be made to the structure of the disclosed embodiments without departing from the scope or spirit of the invention. In view of the foregoing, it is intended that the invention cover modifications and variations of this invention provided they fall within the scope of the following claims and their equivalents.

What is claimed is:

1. A white organic light electroluminescence device, comprising:
a first light emitting unit, comprising:
a first electrode layer;
a first light emitting layer disposed on the first electrode layer, wherein the first light emitting layer comprises a first blue light emitting layer and a red light emitting layer; and
an intrinsic layer disposed between the first blue light emitting layer and the red light emitting layer;
a second light emitting unit, comprising:
a second light emitting layer comprising a second blue light emitting layer and a green light emitting layer; and
a second electrode layer disposed on the second light emitting layer; and
a connecting layer disposed between the first light emitting unit and the second light emitting unit to electrically connect the first light emitting unit and the second light emitting unit in series.

2. The white organic light electroluminescence device as claimed in claim 1, wherein a triplet energy level of the intrinsic layer of the first light emitting layer ranges from a triplet energy level of the first blue light emitting layer to a triplet energy level of the red light emitting layer.

3. The white organic light electroluminescence device as claimed in claim 1, wherein a thickness of the intrinsic layer ranges from 1 nanometer (nm) to 40 nm.

4. The white organic light electroluminescence device as claimed in claim 1, wherein the first blue light emitting layer of the first light emitting layer comprises a blue fluorescent material and the red light emitting layer of the first light emitting layer comprises a red phosphorescence material.

5. The white organic light electroluminescence device as claimed in claim 4, wherein a light emitting wavelength of the blue fluorescent material ranges from 440 nm to 470 nm.

6. The white organic light electroluminescence device as claimed in claim 4, wherein a light emitting wavelength of the red phosphorescence material ranges from 590 nm to 650 nm.

7. The white organic light electroluminescence device as claimed in claim 1, wherein the second blue light emitting layer of the second light emitting layer comprises a blue phosphorescence material and the green light emitting layer of the second light emitting layer comprises a green phosphorescence material.

8. The white organic light electroluminescence device as claimed in claim 7, wherein a light emitting wavelength of the blue phosphorescence material ranges from 470 nm to 480 nm.

9. The white organic light electroluminescence device as claimed in claim 7, wherein a light emitting wavelength of the green phosphorescence material ranges from 500 nm to 570 nm.

10. The white organic light electroluminescence device as claimed in claim 1, further comprising:
a first hole injection layer disposed between the first electrode layer and the first light emitting layer;
a first hole transport layer disposed between the first electrode layer and the first light emitting layer;
a first electron transport layer disposed between the connecting layer and the first light emitting layer;
a second hole injection layer disposed between the second light emitting layer and the connecting layer;
a second hole transport layer disposed between the second light emitting layer and the connecting layer;
a second electron injection layer disposed between the second light emitting layer and the second electrode layer; and
a second electron transport layer disposed between the second light emitting layer and the second electrode layer.
